(19) United States
(12) Patent Application Publication
(10) Pub. No.: US 2014/0053036 A1
(43) Pub. Date: Feb. 20, 2014

(54) DEBUGGING MULTIPLE EXCLUSIVE SEQUENCES USING DSM CONTEXT SWITCHES

(71) Applicants: Scott P. Nixon, Fort Collins, CO (US); Eric M. Rentschler, Steamboat Springs, CO (US)

(72) Inventors: Scott P. Nixon, Fort Collins, CO (US); Eric M. Rentschler, Steamboat Springs, CO (US)

(21) Appl. No.: 13/586,622

(22) Filed: Aug. 15, 2012

(51) Int. Cl. G01R 31/3177

(52) U.S. Cl. 714/734; 714/E11.155

(57) ABSTRACT

A system and method for efficiently debugging an integrated circuit with on-die hardware. A processor core includes an on-die debug state machine (DSM). The DSM includes multiple programmable storage elements for storing parameter values corresponding to multiple contexts. Each context is associated with a given one of multiple instruction sequences, such as at least threads and power-performance states. The DSM detects a sequence identifier (ID) and selects a context based on the sequence ID. The corresponding parameter values are used by transition conditions (triggers) and taken debug actions in a finite state machine (FSM) within the DSM. Each state and transition in the FSM is used by each one of the multiple contexts. The programmable DSM shares many resources, rather than replicating them, while being used for multiple sequences.

### BACKGROUND

1. Field of the Invention

This invention relates to computing systems, and more particularly, to efficiently debugging an integrated circuit with on-die hardware.

2. Background

The higher integration of functionality on integrated circuits (ICs) has been achieved with the reduction in geometric dimensions of devices and metal routes on semiconductor chips. Testing methods and systems attempt to identify any faulty behavior of these complex ICs. The faults may be caused by logic design errors or manufacturing processing defects. For debugging fabricated chips, automatic test equipment (ATE) and logic analyzers may be used to provide given input values to the fabricated chips. These options use external links to connect to the chip being tested and may not provide an accurate representation of the conditions as they exist during normal system operation. Additionally, when a fault is detected during debugging, designers tap signals of interest for determining the cause of the error. Errors that have already occurred, though, are often difficult to repeat and reconstruct. The investigative process may be cumbersome, ineffective, and consume many hours. Further, these options may be relatively expensive.

An IC may include an on-die debug state machine (DSM) for investigating proper functionality of the on-die hardware. The DSM may receive triggers from multiple sources and select a given action based on the triggers. The multiple sources may include a processor core, other DSMs, a hub or chipset, and the like. Both the triggers and the actions may be programmable to offer debug flexibility. The DSM may also provide control of local debug functions.

On-die circuitry, such as the DSM, allows an IC to investigate its functionality without the disadvantages of off-chip test equipment. However, this on-die circuitry consumes on-die real estate that won't be used during real-time computing use after shipment. Additionally, resources are tightly constrained, and thus, limited for debug circuitry for tracking multiple exclusive time-sharing sequences. Examples of these multiple sequences may include individual processes or finer-grain threads used in chip multi-threading (CMT) systems and simultaneous multi-processing (SMP) systems. Compilers may extract parallelized tasks from program code and the IC may have a deep pipeline for simultaneously performing parallel tasks. In hardware-level multi-threading, a simultaneous multi-threaded IC executes instructions from different software processes at the same time. Another example of multiple sequences includes multiple power-performance states used on an IC.

For on-die debug circuitry, simply replicating resources for each simultaneous thread or sequence that needs to be tracked is a straightforward and quick approach. However, simply replicating resources typically overruns the die physical constraints.

In view of the above, efficient methods and systems for efficiently debugging an integrated circuit with on-die hardware are desired.

### SUMMARY OF EMBODIMENTS

Systems and methods for efficiently debugging an integrated circuit with on-die hardware are contemplated. In various embodiments, an IC, such as a processor including one or more processor cores, is described. In the processor related embodiment, each core may be a general-purpose, single-instruction-multiple-data (SIMD), or an application specific core. The IC includes an on-die debug state machine (DSM). The DSM may be included in at least one of the processor cores. The DSM includes multiple storage elements that may be programmed with multiple parameter values associated with multiple contexts. Each context may correspond to a given one of multiple instruction sequences. Examples of instruction sequences include a software process, a software thread, a system-level transaction, and a power-performance state (p-state).

During execution of a test vector on the processor core with a DSM, the DSM detects a sequence identifier (ID) and selects one of the programmed sets of parameter values corresponding to a given one of the multiple contexts based on the sequence ID. The DSM includes a finite state machine (FSM). Each state and transition in the FSM may be used by each one of the multiple contexts. Each transition condition (trigger) and corresponding taken debug action in the FSM depends on the parameter values specific to the context selected by the sequence ID. Therefore, the programmable DSM may share a lot of resources while being used for multiple sequences. The on-die hardware for a particular DSM may not be replicated for each sequence that may operate on the hardware being tested by the particular DSM.

These and other embodiments will be further appreciated upon reference to the following description and drawings.

### BRIEF DESCRIPTION OF THE DRAWINGS

FIG. 1 is a generalized block diagram of one embodiment of an IC, in particular a processor.

FIG. 2 is a generalized block diagram of one embodiment of state diagrams for one and two sequences.

FIG. 3 is a generalized block diagram of one embodiment of state diagrams for two sequences.

FIG. 4 is a generalized block diagram of one embodiment of a debug context selector.

FIG. 5 is a generalized flow diagram of one embodiment of a method for efficiently debugging an integrated circuit with on-die hardware for multiple independent sequences.

While the invention is susceptible to various modifications and alternative forms, specific embodiments are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the spirit and scope of the present invention as defined by the appended claims.

### DETAILED DESCRIPTION OF EMBODIMENT(S)

In the following description, numerous specific details are set forth to provide a thorough understanding of the present invention. However, one having ordinary skill in the art should recognize that the invention might be practiced without these specific details. In some instances, well-known circuits, structures, and techniques have not been shown in detail to avoid obscuring the present invention.

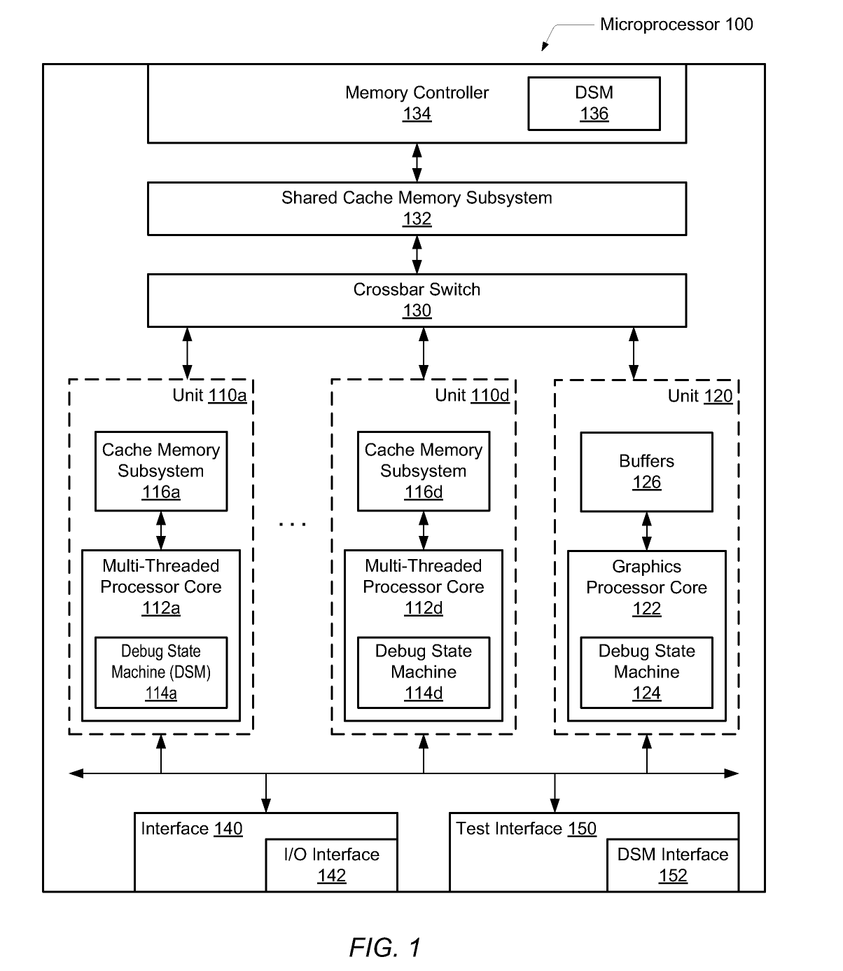

Referring to FIG. 1, a generalized block diagram of one embodiment of an IC 100. In the description below, IC 100 is embodied as a processor although other types of ICs could also be employed. Accordingly, for ease of understanding IC 100 will be referred to herein as processor 100. As used herein, the term processor may refer to a general purposes microprocessor, graphics processor, or other type of processor. One or more components within the processor 100 may include a debug state machine (DSM) for investigating proper functionality of the on-die hardware. Each DSM may receive triggers from multiple sources and select a given action based on the triggers. The sources may include components within a same core or controller, other on-die components outside of the same core or controller, and additionally off-die components.

Multiple exclusive time-sharing sequences may operate on processor 100. Sequences may include software processes, software threads, system-level transactions, power-performance states (p-states), and so forth. A sequence may include one or more instructions to be executed on an IC under test that is scheduled by the OS or the on-die hardware. A sequence identifier (ID) may be used to distinguish between sequences. For example, a process ID, a thread ID, a system-level transaction ID, a p-state ID, and the like may be used. Each sequence may share hardware resources within the IC with other sequences. One or more of execution units, queues, schedulers, process state, memory space, and so forth may be shared while one or more other resources are not shared.

One or more processor cores in the processor 100 may execute multi-threaded applications. Additionally, the processor 100 may operate under one of multiple power-performance states. Further, multiple independent system-level transaction levels may operate on processor 100. Each of a process, a thread, and a power-performance state (p-state) is an example of a sequence. The DSMs in the processor 100 may track statistics and operating behavior for debug reasons of one or more types of sequences operated on processor 100.

The DSMs provide state information, stored parameters, and combinatorial control logic for testing the on-die hardware during processing of independent sequences. Rather than replicate a complete instantiation of a DSM for each sequence processed by the hardware, some static resources, such as state and stored parameters, may be shared. Dynamically changing values dependent on a given sequence may be separately stored. However, a significant portion of the resources in the DSM may correspond to the static resources. Therefore, the additional on-die real estate consumed for adding debug hardware for each additional thread may be greatly reduced. Before providing more details, a further description of the components in the processor 100 is given.

In various embodiments, the illustrated functionality of processor 100 is incorporated upon a single integrated circuit. As shown, processor 100 may include one or more general-purpose processing units 110a-110d. Each of the processing units 110a-110d may include a general-purpose, multi-threaded processor core and a corresponding cache memory subsystem. For example, the processing unit 110a includes a multi-threaded processor core 112a and a corresponding cache memory subsystem 116a. Similarly, the processing unit 110d includes a multi-threaded processor core 112d and a corresponding cache memory subsystem 116d.

Each of the processor cores 112a-112d may include a superscalar microarchitecture with one or more multi-stage pipelines. A multi-thread software application may have each of its software threads processed by a separate pipeline within a respective one of the processor cores 112a-112d. Alternatively, a pipeline that is able to process multiple threads via control at certain function units may process each one of the threads. In yet other examples, each one of the threads may be processed by a pipeline with a combination of dedicated resources to a respective one of the multiple threads and shared resources used by all of the multiple threads. In various embodiments, each of the processor cores 112a-112d includes circuitry for processing instructions according to a given general-purpose instruction set. For example, the x86® instruction set architecture (ISA) may be selected. Alternatively, the x86-64®, Alpha®, PowerPC®, MIPS®, SPARC®, PA-RISC®, or any other instruction set architecture may be selected.

Generally, each of the processor cores 112a-112d accesses a level-one (L1) cache for data and instructions. There may be multiple on-die levels (L2, L3 and so forth) of caches. One or more of these levels of caches may be located outside the processor core and within a respective one of the cache memory subsystems 116a-116d. Interfaces between the different levels of caches may comprise any suitable technology.

Additionally, processor 100 may include one or more application specific cores. The application specific cores may include a graphics processing unit (GPU), another type of single-instruction-multiple-data (SIMD) core, a digital signal processor (DSP), and so forth. In the embodiment shown, processor 100 includes a shared processing unit 120 with a heterogeneous core, such as the graphics processor core 122. The processing unit 120 may also include data storage buffers 126. The graphics processor core 122 may include multiple parallel data paths. Each of the multiple data paths may include multiple pipeline stages, wherein each stage has multiple arithmetic logic unit (ALU) components and operates on a single instruction for multiple data values in a data stream. In some embodiments, two or more pipeline stages within the graphics processor core 122 may be operating on an instruction corresponding to a different sequence, such as a thread, than other pipeline stages.

Similar to the general-purpose processor cores 112a-112d including a respective one of the DSMs 116a-116d, the graphics processor core 122 includes a DSM 126. Although the processor 100 is shown with multiple heterogeneous, multi-threaded cores as an example, it is possible and contemplated that processor 100 has a single multi-threaded processor core with on-die real estate for a debug state machine (DSM).

Processor 100 may also include a shared cache memory subsystem 132 connected to each of the processing units 110a-110d and 120 through a crossbar switch 130. Both the crossbar switch 130 and on-die cache controllers may maintain a coherence protocol. The processing unit 120 may be able to both directly access both local memories and off-chip memory via the crossbar switch 130 and the memory controller 134.

Memory controller 134 may be used to connect the processor 100 to off-die memory. Memory controller 134 may comprise control circuitry for interfacing to memories. Memory controller 134 may follow memory channel protocols for determining values used for information transfer, such as a number of data transfers per clock cycle, signal voltage levels, signal timings, signal and clock phases and clock frequencies. Additionally, memory controller 134 may include request queues for queuing memory requests. The off-die memory may include one of multiple types of dynamic random access memories (DRAMs). The DRAM may be further connected to lower levels of a memory hierarchy, such as a disk memory and offline archive memory. Similar to the processing units 110a-110d and 120, memory controller 134 may also include a debug state machine (DSM) 136.

The interface 140 may include integrated channel circuitry to directly link signals to other processing nodes, which include another processor. The interface 140 may utilize one or more coherence links for inter-node access of processor on-die caches and off-die memory of another processing node. Examples of the technology include HyperTransport and QuickPath. The input/output (I/O) interface 142 generally provides an interface for I/O devices off the processor 100 to the shared cache memory subsystem 132 and processing units 110a-110d and 120. I/O devices may include many variations of computer peripheral devices.

The I/O interface 142 may additionally communicate with a platform and input/output (I/O) controller hub (not shown) for data control and access. The platform and I/O controller hub may interface with different I/O buses according to given protocols. The hub may respond to control packets and messages received on respective links and generate control packets and response packets in response to information and commands received from the processor 100. The hub may perform on-die the operations typically performed off-die by a conventional southbridge chipset. The hub may also include a respective DSM.

The test interface 150 may provide an interface for testing the processor 100 according to a given protocol, such as the IEEE 1149.1 Standard Test Access Port and Boundary-Scan Architecture, or the Joint Test Action Group (JTAG) standards. The test interface 150 may be used to program each one of the DSMs 114a-114d, 124, and 134 in the processor 100. Programming a given DSM of the DSMs 114a-114d, 124, and 134 may include writing particular values in registers corresponding to the given DSM. Programming the given DSM may determine to which triggers the given DSM responds and the type of action taken in the response.

The DSMs 114a-114d, 124, and 134 may each be programmed differently. Alternatively, two or more of the DSMs 114a-114d, 124, and 134 may be programmed in a similar manner. In addition, any given one of the DSMs 114a-114d, 124, and 134 may take a particular action in response to a particular triggering event regardless of the performed programming. The DSM interface 152 may provide an interface for off-chip components with a DSM to communicate with the DSMs 114a-114d, 124 and 136.

A potential trigger event may include reaching a particular pipeline stage in a multi-stage pipeline in a processor core. In some embodiments, in response to determining a potential trigger event has occurred in a processor core, a corresponding one of the DSMs 114a-114d and 124 may perform a context switch based on an independent sequence. The independent sequence may be identified by a corresponding sequence ID. For example, a process ID, a thread ID, a system-level transaction ID, or other may be used as a sequence ID. The sequence ID may also be referred to as a context-switch ID as this ID may be used to select a given context from multiple available contexts.

In other embodiments, a change in the context-switch ID may cause a corresponding one of the DSMs 114a-114d and 124 to perform a context switch. Later, reaching a potential trigger event, such as a particular pipeline stage in the multi-stage pipeline, may cause a trigger event that is handled by a corresponding one of the DSMs 114a-114d and 124. For example, the DSM may perform a trigger-to-action mapping and perform or initiate the corresponding action. A sequence identifier (ID) may be used to select a context. When a corresponding context is selected, thresholds, other transition condition parameters, next-state and action parameters, and the like that correspond to the selected context may be used to determine whether a given trigger event has occurred and which resulting action should be taken. For example, when a retirement pipeline stage is reached, a count of a number of clock cycles since the last time an instruction associated with the context has been retired may be updated and/or compared to an associated threshold.

Continuing with the above example, if the count increments and exceeds the threshold associated with the selected context, one or more resulting actions may be taken. Examples of actions may include starting or marking a trace to be stored in a trace capture buffer, generating an interrupt or some other trigger for external test analysis equipment, stopping one or more selected clock signals, notifying one or more other DSMs, and so forth. Examples of trigger-to-action mappings and the general use of DSMs include multiple implementations, see E. Rentschler, Debug State Machine and Processor Including the Same, U.S. Patent Publication Number 2012/0144240, filed on Dec. 2, 2010, and E. Rentschler, Debug State Machines and Methods of Their Operation, U.S. Patent Publication Number 2012/0151263, filed on Apr. 27, 2011.

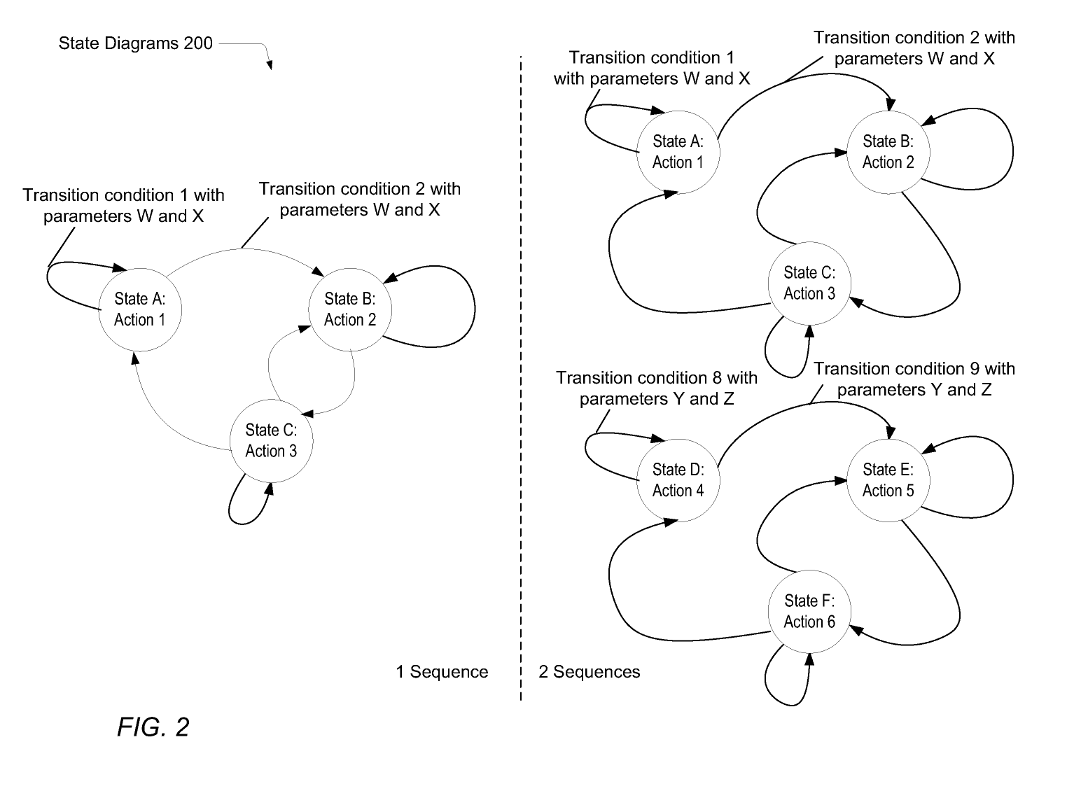

Turning now to FIG. 2, a generalized block diagram of one embodiment of state diagrams 200 for one and two sequences is shown. A sequence may be a given thread, a given system-level transaction, a given power-performance state (p-state), and the like. Although three states are shown as an example in FIG. 2 for each of the state diagrams, other embodiments may comprise a different number of states.

The state diagrams may generally be used within a given DSM. Each state within a state diagram may transition from one state to another state as one or more associated transaction conditions are satisfied. One or more actions may occur as a result of the satisfied transaction conditions or as a given state is reached. For example, using general parameters W and X, one or more qualifying conditions may be evaluated. If the transaction condition 1 is satisfied using the general parameters W and X, then the state diagram remains in State A. In State A, the Action 1 has occurred once upon reaching State A or is continually performed as the current state remains in State A. In one example, the transition condition 1 may include a particular count is below a threshold. The parameters W and X may be used to both select a given count to test and the threshold to compare against.

Continuing with the above example, using the general parameters W and X, if the transaction condition 2 is satisfied, then a transition from State A to State B may occur. In State B, the Action 2 has occurred once upon reaching State B or is continually performed as the current state remains in State B. In one example, the transition condition 2 may use the same particular count used for transition condition 1 and is satisfied when this particular count has exceeded a threshold. In some examples, this threshold may be the same threshold used for transition condition 1. In other example, this threshold is different from the threshold used for transition condition 1.

Each of the States A-C may have one or more associated transition conditions. Although seven total transition conditions are shown as an example in FIG. 2 for the States A-C, other embodiments may comprise a different number of transition conditions. A design team may write the qualifying conditions, the parameters, the transitions, the states, and the actions associated with the states in the state diagrams. Writing particular registers associated with the state diagram, the on-die hardware that implements the state diagram may be programmed. The state diagram with the States A-C may be associated with a given single sequence.

For hardware that processes two independent sequences, the resources for the state diagram with States A-C may be replicated. The state diagram with States D-F may use a same number of states, a same number of actions, a same number of state transitions, and similar qualifying conditions. The particular qualifying conditions, parameters, and actions used for States D-F may be different from the values used for States A-C. The values may be set and the state diagram for States D-F may be programmed in a similar manner as the previous state diagram. For example, the transition conditions 8 and 9 using parameters Y and Z may be similar to the transition conditions 1 and 2 using parameters W and X. Each of the conditions may be comparing a count to a threshold. However, the selection of the count value to compare and the thresholds may differ. Rather than replicate all of the resources for state diagrams used by multiple independent sequences, some of the resources may be shared.

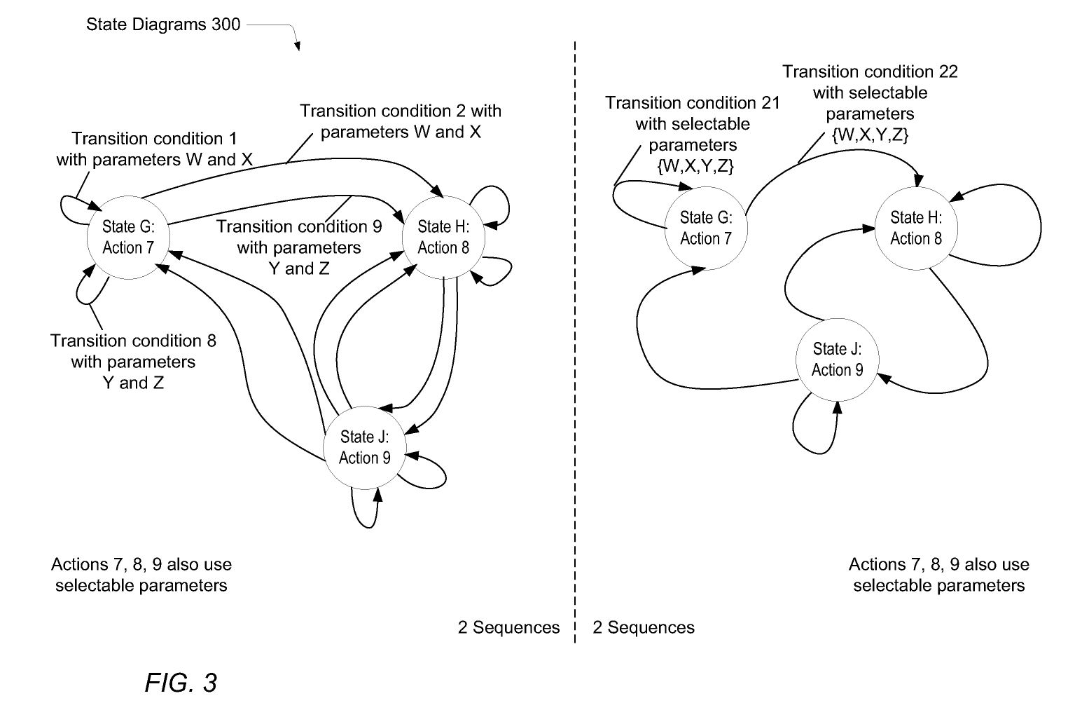

Turning now to FIG. 3, a generalized block diagram of one embodiment of state diagrams 300 for two sequences is shown. Parameters, transition conditions, states and actions described previously are labeled in a similar manner. The first state diagram shown on the left for two sequences uses a same number of states as the state diagram for one sequence. The states and actions may be selected based on a sequence ID.

In one example, referring again to FIG. 2, a multiplexer may select between State A and State D using the sequence ID to determine the value for State G. Similarly, States B and E may be choices for State H, and States C and F may be choices for State J. In a similar manner, Action 7 may be selected based on the sequence ID from each of Action 1 and Action 4. Similarly, Actions 2 and 5 may be choices for Action 8, and Actions 3 and 6 may be choices for Action 9. However, if each of Action 1 and Action 4 are the same, such as begin a trace and stop a particular clock, then no selection for Action 7 may occur. Rather, Action 7 is the same action as used for each of Action 1 and Action 4. An identifier of a given clock signal, trace capture buffer, and so forth may change, but the action is the same. The values for the identifiers may be stored and selected based on a sequence identifier. The same may be true for each of Action 8 and Action 9.

As shown, the seven transition conditions for each of the previous two state diagrams are used in the single state diagram for two sequences. Therefore, referring again to FIG. 3, the state diagram on the left includes fourteen transition conditions. However, if the same on-die hardware is being tested with two independent sequences, the qualifying conditions and transition conditions may be similar or the same. A multiplexer may select between transition condition 1 and transition condition 8 using the sequence ID to determine the value for transition condition 21. Similarly, transition conditions 2 and 9 may be choices for transition condition 22, which are selected based on the sequenced ID. Therefore, the state diagram used in a programmable DSM may share a lot of resources while being used for multiple instruction sequences. The on-die hardware for a particular DSM may not be replicated for each sequence that may operate on the hardware being tested by the particular DSM.

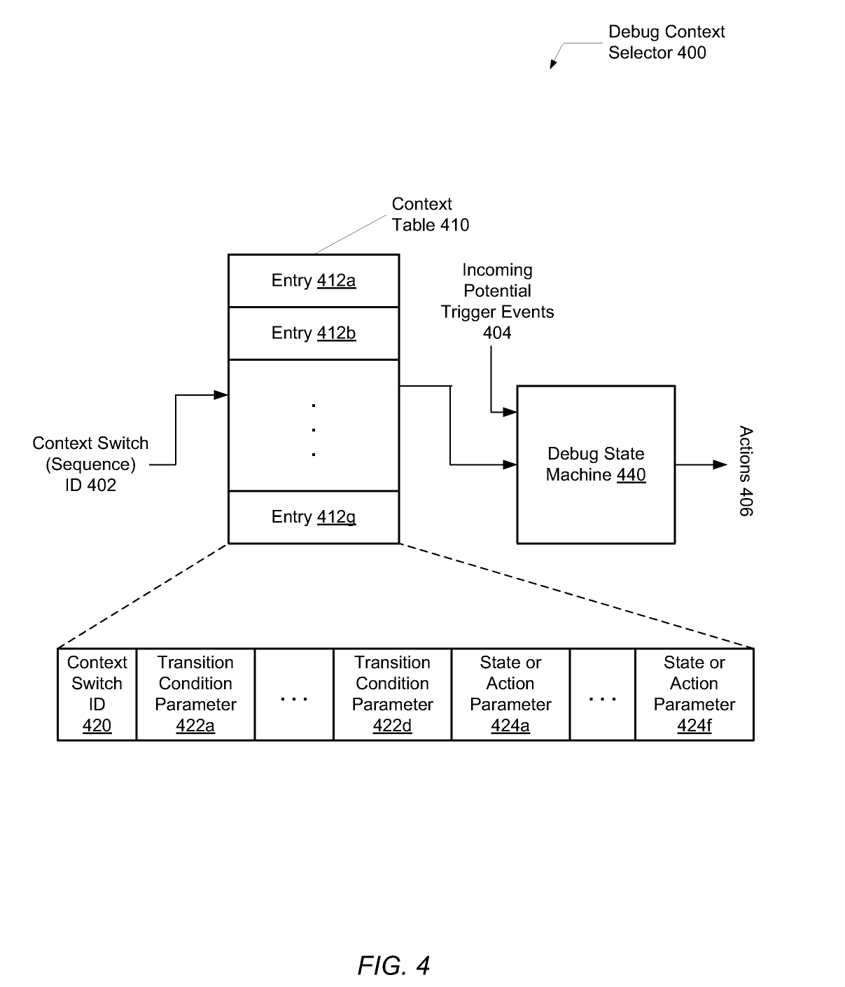

Referring now to FIG. 4, a generalized block diagram of one embodiment of a debug context selector 400 is shown. In some embodiments, a multiplexer may be used to select between debug values based on a context switch identifier (ID). The context switch ID may be a sequence ID. When a number of contexts increases to a significantly high value, a context table 410 may be used. Whether a multiplexer, the context table 410, or other selection logic is used, the selection may be based on a context switch ID, such as a sequence ID. The sequence ID may be a thread ID, a system-level transaction ID, a power-performance state (p-state) ID, and so forth. The debug values being selected may be stored in programmable registers.

As shown, the context table 410 may include multiple entries 412a-412g. A context switch ID 402 may index the context table 410 and the values stored in a corresponding one of the entries 412a-412g may be read out. These stored values being read out may be combined with incoming potential trigger events 404 and sent to a corresponding DSM 440. The state diagram logic within the DSM 440 may determine both whether a given trigger event has occurred and the corresponding trigger-to-action mapping to process. The actions 406 may be selected and performed based on these determinations by DSM 440. In various embodiments, the debug context selector is located outside of a respective DSM as shown. In other embodiments, the debug context selector is included within the respective DSM and the DSM receives the context-switch ID 402 as an input.

Each one of the entries 412a-412g may store various debug information associated with a particular sequence. For example, the stored entries may include a context switch ID 420, transition condition parameters 422a-422d, and state or action parameters 424a-424f. Examples of the transition condition parameters 422a-422d may include an identifier of a count or other stored value to compare, threshold values, an identifier of a particular hardware error or condition to inspect, identifiers of on-die performance monitors to inspect, identifiers of on-die control and status registers to inspect, and so forth.

Examples of the state or action parameters 424a-424f may include identifiers of one or more clocks, encoded enable and disable clock operations, identifiers of trace capture buffers, encoded start and stop trace recording operations, identifiers of interrupts to generate, identifiers of triggers to send to external test analysis equipment, identifiers or addresses of microcode programs to execute, an encoded list of control and status registers to assert to trigger other events, and so forth.

In addition, status information, such as a valid bit may be stored in each one of the entries 412a-412g. Further, transition condition operators may be stored. For example, a given transition condition may include one or more logical operators to be used on retrieved parameter values. Two or more sequences may use a different number of operators or different operators in their evaluation expressions. These operators and an indication of the order of use may be stored in the entries 412a-412g.

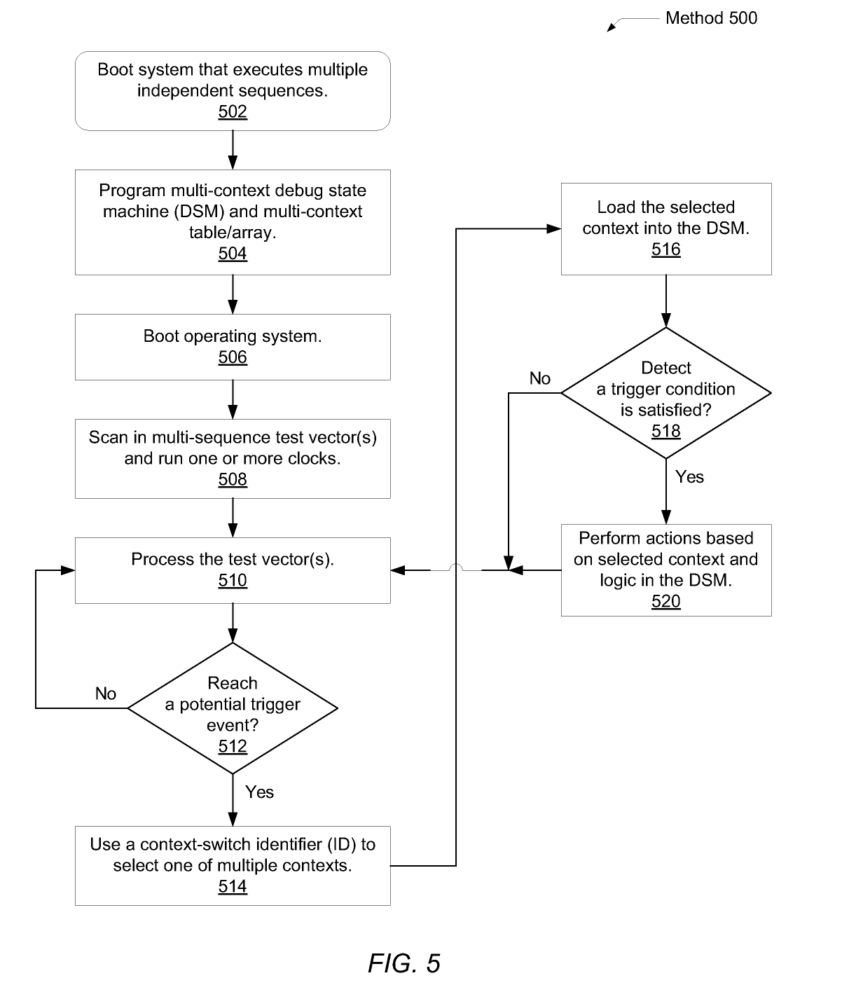

Referring now to FIG. 5, a generalized flow diagram of one embodiment of a method 500 for efficiently debugging an integrated circuit with on-die hardware for multiple independent sequences is illustrated. The components embodied in the computing system described above may generally operate in accordance with method 500. For purposes of discussion, the steps in this embodiment are shown in sequential order. However, some steps may occur in a different order than shown, some steps may be performed concurrently, some steps may be combined with other steps, and some steps may be absent in another embodiment.

In block 502, a system that executes multiple independent sequences is booted. The system may include an integrated circuit (IC) that is able to process instructions for multiple independent sequences. The system may be powered up and corresponding program instructions of a basic input/output software (BIOS) may be executed. In various embodiments, in block 504, some of the instructions in the BIOS may program one or more multi-context debug state machines (DSMs) in the system. In addition, a multi-context table or array may be programmed.

Sequences, again, may include software processes, software threads, system-level transactions, power-performance states (p-states), and so forth. A sequence may include one or more instructions to be executed on an IC under test that is scheduled by the OS or the on-die hardware. A sequence identifier (ID) may be used to distinguish between sequences. For example, a process ID, a thread ID, a system-level transaction ID, a e-state ID, and the like may be used. Each sequence may share hardware resources within the IC with other sequences. One or more of execution units, queues, schedulers, process state, memory space, and so forth may be shared while one or more other resources are not shared.

In block 506, the operating system (OS) may be booted. In block 508, multi-sequence test vectors may be scanned in to the system and one or more clocks may be run to begin processing the test vectors on the hardware for debugging purposes. In block 510, the system processes the test vectors. One of multiple potential trigger events may be reached. An example is a retirement pipeline stage in a multi-stage pipeline may be reached. Although the granularity of context switching may be a clock cycle, wherein a context may be switched each clock cycle, for a high percentage of tests, the granularity may be much larger. For example, test vector instructions may operate for hundreds of cycles for one sequence context, before a switch occurs. Therefore, although a processor core may be able to simultaneously process multiple threads, a given thread may be reaching the retirement pipeline alone. Therefore, no arbitration logic may be used when accessing a corresponding DSM, since two or more threads are not simultaneously attempting to access the DSM. Here, a thread is used as an example of a sequence, but other examples of sequences may also be used.

In some embodiments, two or more threads may be executing simultaneously in the processor core, but only one thread is being monitored for testing purposes. Again, arbitration logic is not used during access of the DSM. The other threads may be running in order to create a simultaneous multi-threading environment for the thread under test. In yet other embodiments, multiple threads are simultaneously executing and two or more of these threads are being monitored. Arbitration logic may be used. However, the complexity of adding arbitration logic may not exceed the resources of replicating the DSM for one or more additional threads to monitor. Otherwise, replication may be used. In addition to arbitration logic, recording an output trace and statistics for a given thread of multiple threads under test over sporadic points-in-time as arbitration logic selects among the candidate threads for access of the DSM may not provide sufficient debugging information. If this type of testing does provide sufficient information, then arbitration logic for accessing the DSM may be used.

If a potential trigger event is reached (conditional block 512), then in block 514, a context-switch identifier (ID) is used to select one of multiple contexts. An example of a potential trigger event may include reaching a given pipeline stage in a multi-stage pipeline. In some embodiments, whether a change occurs in the context-switch ID is determined and a change qualifies a selection of a context. If no change is determined, then the same current context is used. In one example, a processor is executing a thread and the power-performance state (p-state) changes. Therefore, when a retirement pipeline stage is reached, the context-switch ID associated with the new p-state may be used to select one of multiple contexts when the retirement pipeline stage is reached. Alternatively, rather than begin with a potential trigger event, a detected change in the context-switch ID may be used to select one of multiple contexts. Later, when a potential trigger event occurs, such as a particular pipeline stage is reached, the corresponding context is already loaded and a transition condition may begin evaluation to determine whether a trigger has occurred. For example, prior to reaching the retirement pipeline stage, the context-switch ID associated with the new p-state may be used to select one of multiple contexts.

A context-switch ID may be a thread ID, a process ID, a system-level transaction ID, a power-performance state (p-state) ID, and the like. In various embodiments, the context may include multiple values, such as the values previously described as being stored in entries 412a-412g of context table 410. In some embodiments, the context-switch ID is connected to select lines of one or more multiplexers and used to select one set of registers between multiple sets of registers storing context values. In other embodiments, the context-switch ID is used to index a table or array storing context values. A given entry in the table or array is selected based on at least the context-switch ID.

In block 516, the selected context is loaded into the DSM. A satisfied transition condition in the state diagram within the DSM may cause a trigger. If a trigger condition is satisfied (conditional block 518), then in block 520, the DSM performs actions or initiates actions to be performed by other circuitry based on the selected context and logic in the state diagram in the DSM. The state diagram may implement a trigger-to-action mapping. Using context switches and sharing many of the resources of the DSM among multiple independent sequences may significantly increase the capability of the debugging process while minimizing on-die real estate impact.

It is noted that the above-described embodiments may comprise software. In such an embodiment, the program instructions that implement the methods and/or mechanisms may be conveyed or stored on a computer readable medium. Numerous types of media which are configured to store program instructions are available and include hard disks, floppy disks, CD-ROM, DVD, flash memory, Programmable ROMs (PROM), random access memory (RAM), and various other forms of volatile or non-volatile storage. Generally speaking, a computer accessible storage medium may include any storage media accessible by a computer during use to provide instructions and/or data to the computer. For example, a computer accessible storage medium may include storage media such as magnetic or optical media, e.g., disk (fixed or removable), tape, CD-ROM, or DVD-ROM, CD-R, CD-RW, DVD-R, DVD-RW, or Blu-Ray. Storage media may further include volatile or non-volatile memory media such as RAM (e.g. synchronous dynamic RAM (SDRAM), double data rate (DDR, DDR2, DDR3, etc.) SDRAM, low-power DDR (LPDDR2, etc.) SDRAM, Rambus DRAM (RDRAM), static RAM (SRAM), etc.), ROM, Flash memory, non-volatile memory (e.g. Flash memory) accessible via a peripheral interface such as the Universal Serial Bus (USB) interface, etc. Storage media may include microelectromechanical systems (MEMS), as well as storage media accessible via a communication medium such as a network and/or a wireless link.

Additionally, program instructions may comprise behavioral-level description or register-transfer level (RTL) descriptions of the hardware functionality in a high level programming language such as C, or a design language (HDL) such as Verilog, VHDL, or database format such as GDS II stream format (GDSII). In some cases the description may be read by a synthesis tool, which may synthesize the description to produce a netlist comprising a list of gates from a synthesis library. The netlist comprises a set of gates, which also represent the functionality of the hardware comprising the system. The netlist may then be placed and routed to produce a data set describing geometric shapes to be applied to masks. The masks may then be used in various semiconductor fabrication steps to produce a semiconductor circuit or circuits corresponding to the system. Alternatively, the instructions on the computer accessible storage medium may be the netlist (with or without the synthesis library) or the data set, as desired. Additionally, the instructions may be utilized for purposes of emulation by a hardware based type emulator from such vendors as Cadence®, EVE®, and Mentor Graphics®.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. An integrated circuit (IC) comprising:
a debug state machine (DSM) configured to be programmed with a plurality of contexts, each comprising parameter values corresponding to a given one of a plurality of instruction sequences; and
a test interface configured to receive a plurality of test vectors to test the functionality of the IC;
wherein in response to detecting a sequence identifier (ID) during execution of a given one of the plurality of test vectors, the DSM is configured to:
select one of the plurality of contexts based on the sequence ID; and
determine to take one of a plurality of debug actions based on at least the selected context.

2. The integrated circuit as recited in claim 1, wherein the debug state machine comprises a single finite state machine (FSM) operable for each one of the plurality of contexts.

3. The integrated circuit as recited in claim 2, wherein each state and transition in the FSM is used by each one of the plurality of contexts.

4. The integrated circuit as recited in claim 3, wherein each transition condition (trigger) and corresponding debug action in the finite state machine depends on the parameter values specific to a respective context.

5. The integrated circuit as recited in claim 4, wherein the parameter values include at least one of the following: identifiers (IDs) of stored values such as counters, performance monitors, and control and status registers (CSRs), and thresholds to compare against the stored values.

6. The integrated circuit as recited in claim 4, wherein the parameter values include at least one of the following: identifiers of one or more clocks, encoded enable and disable clock operations, identifiers of trace capture buffers, encoded start and stop trace recording operations, and identifiers of triggers to send to external test analysis equipment.

7. The integrated circuit as recited in claim 4, wherein each instruction sequence is associated with at least one of the following: a software process, a software thread, a system-level transaction, and a power-performance state (p-state).

8. The integrated circuit as recited in claim 5, wherein at least one test vector is associated with a different one of the plurality of sequences than at least another test vector of the plurality of test vectors.

9. The integrated circuit as recited in claim 5, wherein the integrated circuit comprises at least one of the following: a general-purpose processor core, a single-instruction-multiple-data (SIMD) core, and an application specific core.

10. A method comprising:
programming a debug state machine in an integrated circuit (IC) with a plurality of contexts, each comprising parameter values corresponding to a given one of a plurality of instruction sequences;
receiving a plurality of test vectors to test the functionality of the IC; and
in response to detecting a sequence identifier (ID) during execution of a given one of the plurality of test vectors on the IC:
selecting one of the plurality of contexts based on the sequence ID; and
determining to take one of a plurality of debug actions defined in the debug state machine based on at least the selected context.

11. The method as recited in claim 10, wherein the debug state machine comprises a single finite state machine (FSM) operable for each one of the plurality of contexts.

12. The method as recited in claim 11, wherein each state and transition in the FSM is used by each one of the plurality of contexts.

13. The method as recited in claim 12, wherein each transition condition (trigger) and corresponding debug action in the finite state machine depends on the parameter values specific to a respective context.

14. The method as recited in claim 13, wherein the parameter values include at least one of the following: identifiers (IDs) of stored values such as counters, performance monitors, and control and status registers (CSRs), and thresholds to compare against the stored values.

15. The method as recited in claim 13, wherein the parameter values include at least one of the following: identifiers of one or more clocks, encoded enable and disable clock operations, identifiers of trace capture buffers, encoded start and stop trace recording operations, and identifiers of triggers to send to external test analysis equipment.

16. The method as recited in claim 13, wherein each instruction sequence is associated with at least one of the following: a software process, a software thread, a system-level transaction, and a power-performance state (p-state).

17. A debug state machine comprising:
a plurality of programmable storage elements configured to be programmed with a plurality of contexts, each comprising parameter values corresponding to a given one of a plurality of instruction sequences;
an interface for receiving at least a sequence identifier (ID); and
control logic, wherein in response to detecting a sequence identifier (ID) during execution of a given one of a plurality of test vectors on an integrated circuit (IC), the control logic is configured to:
select one of the plurality of contexts based on the sequence ID; and
determine to take one of a plurality of debug actions based on at least the selected context.

18. The debug state machine as recited in claim 17, wherein the debug state machine further comprises a single finite state machine (FSM) operable for each one of the plurality of contexts.

19. The debug state machine as recited in claim 18, wherein each state and transition in the FSM is used by each one of the plurality of contexts.

20. The debug state machine as recited in claim 19, wherein each transition condition (trigger) and corresponding debug action in the finite state machine depends on the parameter values specific to a respective context.

21. A non-transitory computer readable storage medium comprising program instructions operable to configure a system for manufacturing an integrated circuit (IC) to cause the IC to perform on-die debugging, wherein the program instructions are executable to:
program a debug state machine in the integrated circuit (IC) with a plurality of contexts, each comprising parameter values corresponding to a given one of a plurality of instruction sequences;
receive a plurality of test vectors to test the functionality of the IC; and
in response to detecting a sequence identifier (ID) during execution of a given one of the plurality of test vectors on the IC:
select one of the plurality of contexts based on the sequence ID; and
determine to take one of a plurality of debug actions defined in the debug state machine based on at least the selected context.

22. The storage medium as recited in claim 21, wherein the instructions comprise a behavioral-level description or a register-transfer level (RTL) description of the hardware functionality of the IC in a programming language that includes at least one of the following: C, Verilog, VHDL, and a database GDS II stream format (GDSII).

23. The storage medium as recited in claim 21, wherein the debug state machine comprises a single finite state machine (FSM) operable for each one of the plurality of contexts.
